(19) United States
(12) Patent Application Publication
(10) Pub. No.: US 2003/0036220 A1
(43) Pub. Date: Feb. 20, 2003

(54) Printed circuit board having plating conductive layer with bumps and its manufacturing method

(76) Inventors: Gorou Ikegami, Shiga (JP); Taro Hirai, Shiga (JP)

Correspondence Address: KATTEN MUCHIN ZAVIS ROSENMAN, 575 MADISON AVENUE, NEW YORK, NY, 10022-2585, US

(21) Appl. No.: 10/205,323

(22) Filed: Jul. 25, 2002

(30) Foreign Application Priority Data
Aug. 20, 2001 (JP) 2001-248867

(51) Int. Cl. H01L 21/44; H01L 21/48; H01L 21/50

(52) U.S. Cl. 438/108; 438/112

(57) ABSTRACT

In a method for manufacturing a printed circuit board, openings are perforated in a first resin substrate. Then, a conductive layer is formed on a surface of the first resin substrate and within the openings of the first resin substrate. Then, a second resin substrate is adhered to the conductive layer by an adhesive layer. Then, the first resin substrate is peeled off from the conductive layer, so that the conductive layer is transferred from the first resin substrate to the second resin substrate.

### BACKGROUND OF THE INVENTION

1. Field of the Invention

The present invention relates to a flip-chip type semiconductor device, and more particularly, to a printed circuit board thereof and its manufacturing method.

2. Description of the Related Art

Flip-chip type semiconductor devices have been developed to meet the requirements of higher performance, smaller and lighter size, and higher speed for electric equipment.

A first prior art flip-chip type semiconductor device (see: FIG. 3 of JP-A-2001-144143) is constructed by a printed circuit board including an insulating substrate and a conductive pattern layer, and a semiconductor pellet including a semiconductor chip with bonding pads and solder bumps thereon. In this case, each bump is formed by a pedestal portion and a tip portion. This will be explained later in detail.

In the above-described first prior art flip-chip type semiconductor device, however, when the bumps are more-fined, it is impossible to form the tip portion of each bump. Also since the bumps are formed one by one, the manufacturing cost is remarkably increased. Further, the tip portion of each bump is buried in the insulating substrate which substantially decreases the distance between the printed circuit board and the semiconductor pellet, so that stress concentration would occur in the electrical connections due to the difference in thermal expansion therebetween.

A second prior art flip-chip type semiconductor device (see: JP-A-63-45888) is constructed by a printed circuit board including a resin substrate, a conductive pattern layer and solder bumps thereon, and a semiconductor pellet including a semiconductor chip with bonding pads. In this case, the conductive pattern layer and the bumps are obtained by transferring them from a conductive substrate to the resin substrate. This also will be explained in detail later.

In the above-described second prior art flip-chip type semiconductor device, however, since a process for etching the conductive substrate is required, the manufacturing cost of the printed circuit board is still remarkably increased.

### SUMMARY OF THE INVENTION

It is an object of the present invention to provide a printed circuit board with bumps capable of decreasing the manufacturing cost.

Another object is to provide a method for manufacturing the above-mentioned printed circuit board.

According to the present invention, in a printed circuit board, a plating conductive pattern layer including bumps is formed on an insulating substrate such as a resin substrate.

Also, in a method for manufacturing a printed circuit board, openings are perforated in a first resin substrate. Then, a conductive layer is formed on a surface of the first resin substrate and within the openings of the first resin substrate. Then, a second resin substrate is adhered to the conductive layer by an adhesive layer. Then, the first resin substrate is peeled off from the conductive layer, so that the conductive layer is transferred from the first resin substrate to the second resin substrate.

### BRIEF DESCRIPTION OF THE DRAWINGS

The present invention will be more clearly understood from the description set forth below, as compared with the prior art, with reference to the accompanying drawings, wherein:

FIG. 1A is a cross-sectional view illustrating a first prior art flip-chip type semiconductor device;

FIG. 1B is an enlargement of the bump of FIG. 1A;

FIG. 2 is a cross-sectional view illustrating a second prior art flip-chip type semiconductor device;

FIGS. 3A through 3H are cross-sectional view for explaining a method for manufacturing the flip-chip type semiconductor device of FIG. 2;

FIG. 4 is a cross-sectional view illustrating an embodiment of the flip-chip type semiconductor device according to the present invention;

FIGS. 5A through 5J are cross-sectional view for explaining a first method for manufacturing the flip-chip type semiconductor device of FIG. 4; and

FIGS. 6A through 6J are cross-sectional view for explaining a second method for manufacturing the flip-chip type semiconductor device of FIG. 4.

### DESCRIPTION OF THE PREFERRED EMBODIMENT

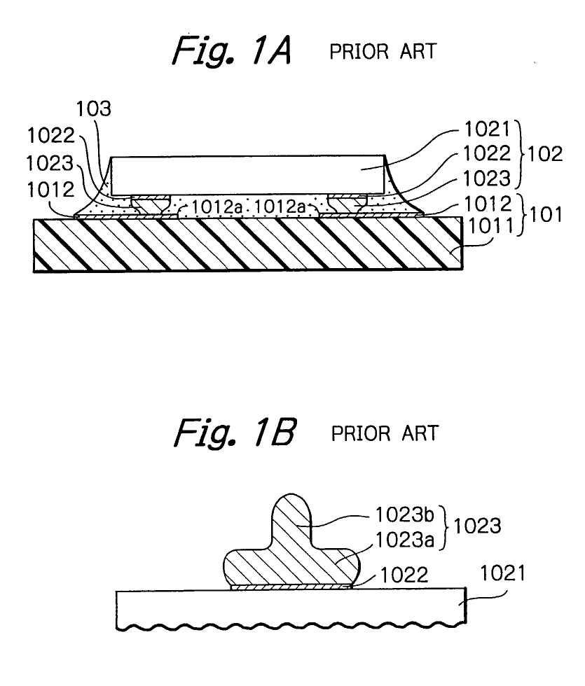

Before the description of the preferred embodiment, prior art flip-chip type semiconductor devices will be explained with reference to FIGS. 1A, 1B, 2 and 3A through 3H.

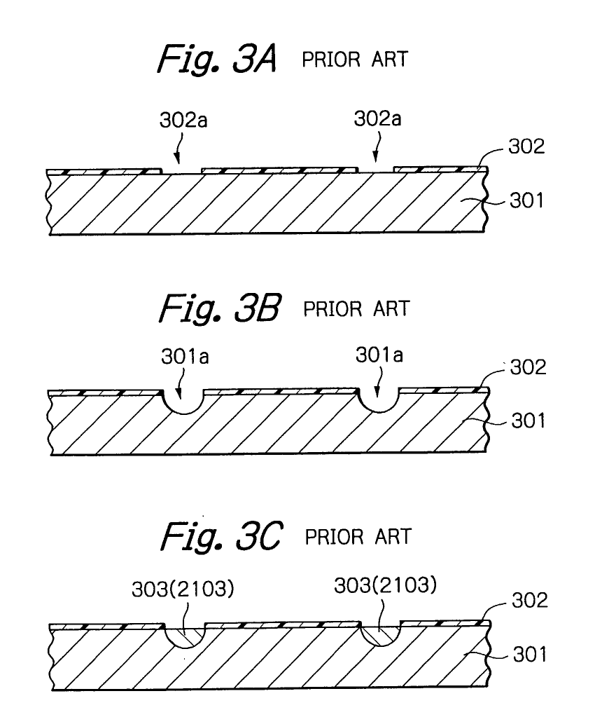

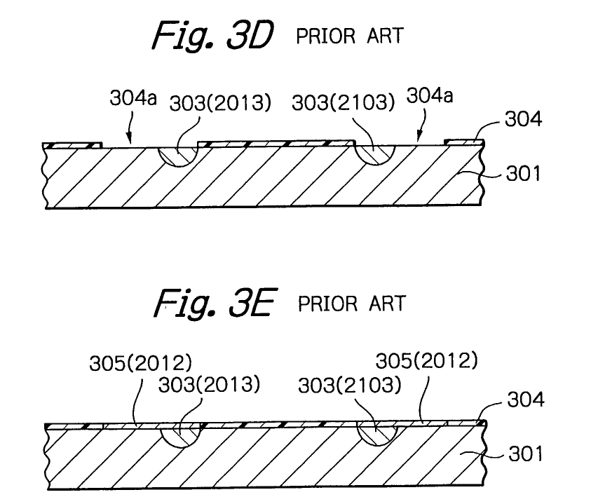

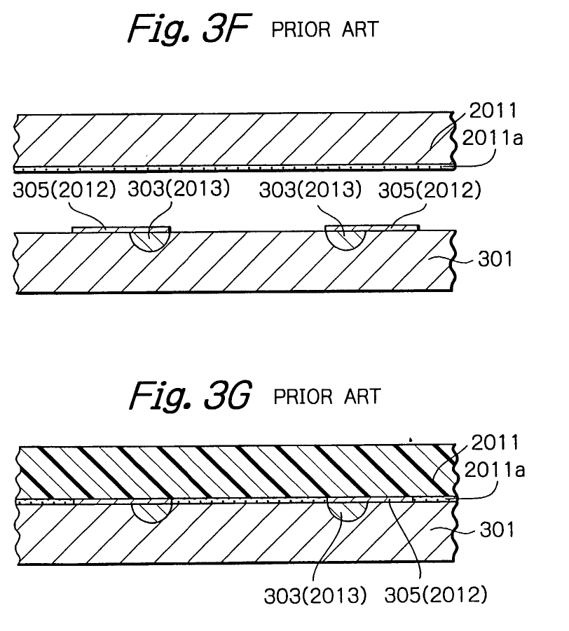

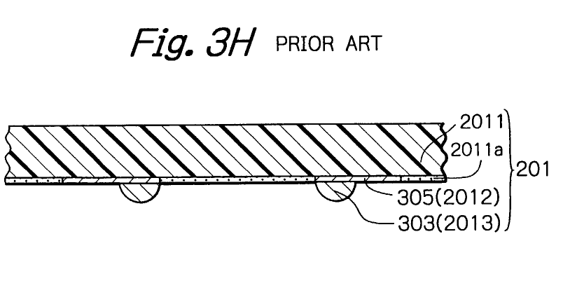

In FIG. 1A, which illustrates a first prior art flip-chip type semiconductor device (see: FIG. 3 of JP-A2001-144143), reference numeral 101 designates a printed circuit board, and 102 designates a semiconductor pellet.

The printed circuit board 101 is constructed by a heat-resistant insulating substrate 1011 made of polyimide resin or epoxy resin and a conductive pattern layer 1012 formed on the insulating substrate 1011. In this case, the conductive pattern layer 1012 is obtained by depositing a conductive layer on the insulating substrate 1011, patterning the conductive layer and covering a photoresist layer (not shown) thereon. In this case, central parts of the conductive pattern layer 1012 exposed through the photoresist layer serve as pad electrodes 1012a, and peripheral parts of the conductive pattern layer 1012 serve as spaced lead electrodes (not shown).

On the other hand, the semiconductor pellet 102 is constructed by a semiconductor chip 1021 on which bonding pads 1022 are formed, and solder balls (bumps) 1023 formed on the bonding pads 1022.

Also, a liquid resin layer 103 is inserted between the printed circuit board 101 and the semiconductor pellet 102 to absorb stress due to the difference in thermal expansion therebetween, thus avoiding stress concentration on the electrical connection therebetween. Also, the resin layer 103 avoids the erosion of the connection layers (not shown) on the semiconductor chip 1021.

In FIG. 1A, when the height of the bumps 1023 greatly fluctuates, it is impossible to sufficiently press all the bumps 1023 against the printed circuit board 101. In order to effectively press all the bumps 1023 against the printed circuit board 101, each of the bumps 1023 is formed by a pedestal portion 1023a and a tip portion 1023b, as illustrated in FIG. 1B. As a result, when the semiconductor pellet 102 is pressed onto the printed circuit board 101 by a thermocompressing method or a heating and ultrasonic bonding method, the tip portions 1023b of the bumps 1023 are deformed to absorb the difference in height between the bumps 1023. Thus, the bumps 1023 can be surely electrically-connected to the electrode pads 1012.

In the flip-chip type semiconductor device of FIGS. 1A and 1B, each of the bumps 1023 is obtained by melting a tip of metal wire supported by a capillary to grow a solder ball and pressing the solder ball against one of the electrode pads 1022 to leave it thereon. In this case, a portion between the melt solder ball and remainder of the metal wire depends on the temperature of the tip of the metal wire. Also, the height of the tip portion 1023b depends upon the diameter of the pedestal portion 1023a. Therefore, when the bumps 1023 are more-fined, it is impossible to form the tip portion 1023b of each of the bumps 1023.

Also, since the bumps 1023 are formed one by one, the manufacturing cost is remarkably increased.

Further, since the insulating substrate 1011 is made of resin, when a thermocompressing method or the like is performed upon the semiconductor chip 102, the insulating substrate 1011 is deformed so that the bumps 1023 may be partly buried in the insulating substrate 1011. As a result, the distance between the printed circuit board 101 and the semiconductor pellet 102 is substantially decreased, so that stress concentration would occur in the electrical connections due to the difference in thermal expansion between the insulating substrate 1011 and the semiconductor chip 1021.

Note that the bumps 1023 of the semiconductor pellet 102 can be provided on the pad electrodes 1012a of the printed circuit board 101; however, even in this case, the above-mentioned problems would occur.

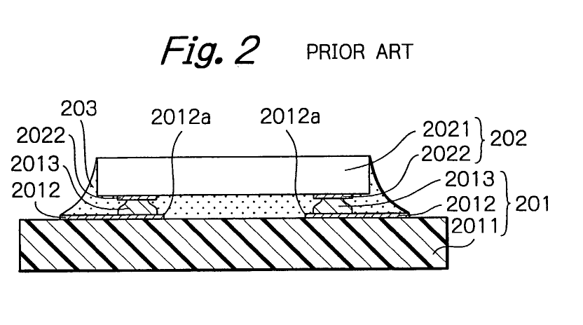

In FIG. 2, which illustrates a second prior art flip-chip type semiconductor device (see: JP-A-63-45888), reference numeral 201 designates a printed circuit board, and 202 designates a semiconductor pellet.

The printed circuit board 201 is constructed by a heat-resistant insulating substrate 2011 made of polyimide resin or epoxy resin, a conductive pattern layer 2012 formed on the insulating substrate 2011 and bumps 2013 formed on the conductive pattern layer 2012. In this case, the conductive pattern layer 2012 and bumps 2013 are obtained by forming a conductive pattern layer and bumps in a conductive substrate and transferring the conductive pattern layer and the bumps from the conductive substrate to the insulating substrate 2011. This will be explained later in detail. Also, in this case, central parts of the conductive pattern layer 2012 exposed through a photoresist layer (not shown) serve as pad electrodes 2012a, and peripheral parts of the conductive pattern layer 2012 serve as spaced lead electrodes (not shown).

On the other hand, the semiconductor pellet 202 is constructed by a semiconductor chip 2021 on which bonding pads 2022 are formed.

Also, a liquid resin layer 203 is inserted between the printed circuit board 201 and the semiconductor pellet 202 to absorb stress due to the difference in thermal expansion therebetween, thus avoiding stress concentration on the electrical connection therebetween. Also, the resin layer 203 avoids the erosion of the connection layers (not shown) on the semiconductor chip 2021.

A method for manufacturing the flip-chip type semiconductor device of FIG. 2 is explained next with reference to FIGS. 3A through 3H.

First, referring to FIG. 3A, a photoresist pattern layer 302 is formed on a conductive substrate 301. In this case, the photoresist pattern layer 302 has openings 302a corresponding to the bumps 2013a of FIG. 2.

Next, referring to FIG. 3B, the conductive substrate 301 is etched by using the photoresist pattern layer 302 as a mask, to form semi-spherical recesses 301a in the conductive substrate 301.

Next, referring to FIG. 3C, a conductive layer 303 (the bumps 2103 of FIG. 2) is buried by a plating process in the semi-spherical recesses 301a. Then, the photoresist pattern layer 302 is removed.

Next, referring to FIG. 3D, a photoresist pattern layer 304 is formed on the conductive substrate 301. In this case, the photoresist pattern layer 304 has openings 304a corresponding to the conductive pattern layer 2012 of FIG. 2.

Next, referring to FIG. 3E, a conductive layer 305 (the conductive pattern layer 2012 of FIG. 2) is buried by a plating process in the openings 304a of the photoresist pattern layer 304. Then, the photoresist pattern layer 304 is removed.

Next, referring to FIG. 3F, an insulating substrate 2011 made of epoxy resin or the like associated with an adhesive layer 2011a is moved down to the conductive substrate 301.

Next, referring to FIG. 3G, a themocompressing operation is carried out, so that the insulating substrate 2011 is surely adhered to the conductive layer 305 (the conductive pattern layer 2012). Then, an etching operation is performed upon the conductive substrate 301, to obtain a circuit board 301 as illustrated in FIG. 3H.

Thus, the conductive pattern layer 2012 and the bumps 2013 are transferred from the conductive substrate 301 to the insulating substrate 2011.

Finally, the insulating substrate 201 of FIG. 3H is reversed, and then, a semiconductor pellet 202 of FIG. 2 is pressed thereto by a thermocompressing method or a heating and ultrasonic bonding method. Also, a resin layer 203 of FIG. 2 is inserted between the circuit board 201 and the semiconductor pellet 202 to complete the flip-chip type semiconductor device of FIG. 2. Note that the adhesive layer 2011a is not shown in FIG. 2.

In the flip-chip type semiconductor device of FIGS. 2 and 3A through 3H, however, since an etching process for the conductive substrate 301 is required, the manufacturing cost is still increased.

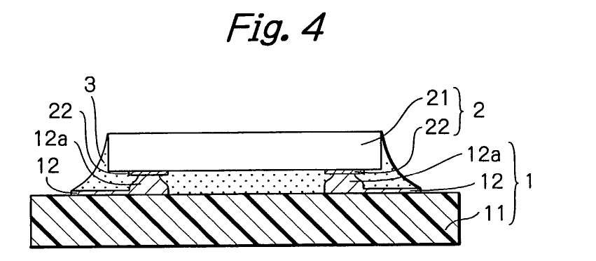

In FIG. 4, which illustrates an embodiment of the flip-chip type semiconductor device according to the present invention, reference numeral 1 designates a printed circuit board, and 2 designates a semiconductor pellet.

The printed circuit board 1 is constructed by a heat-resistant insulating substrate 11 made of polyimide resin or epoxy resin and a conductive pattern layer 12 including bumps 12a formed on the insulating substrate 11. In this case, the conductive pattern layer 12 with the bumps 12a are obtained by forming a conductive pattern layer with bumps in another resin substrate (not shown) and transferring the conductive pattern layer with bumps from the resin substrate to the insulating substrate 11. This will be explained later in detail. Also, in this case, peripheral parts of the conductive pattern layer 12 serve as spaced lead electrodes (not shown).

On the other hand, the semiconductor pellet 2 is constructed by a semiconductor chip 21 on which bonding pads 22 are formed.

Also, a liquid resin layer 3 is inserted between the printed circuit board 1 and the semiconductor pellet 2 to absorb stress due to the difference in thermal expansion therebetween, thus avoiding stress concentration on the electrical connection therebetween. Also, the resin layer 3 avoids the erosion of the connection layers (not shown) on the semiconductor chip 21.

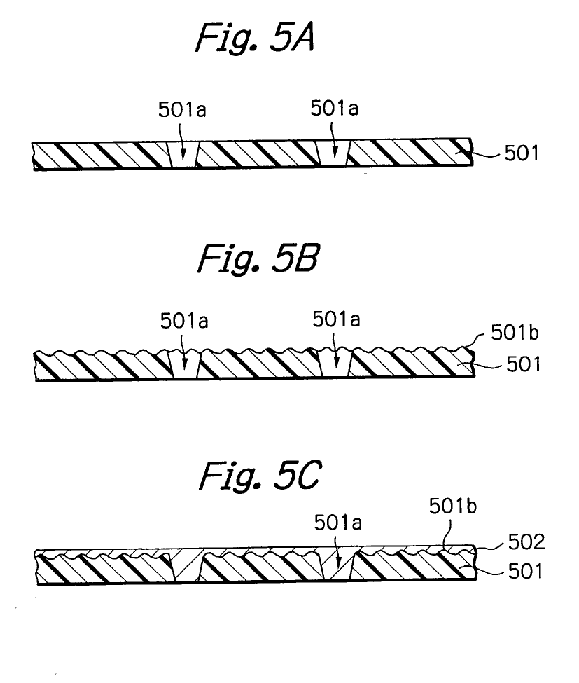

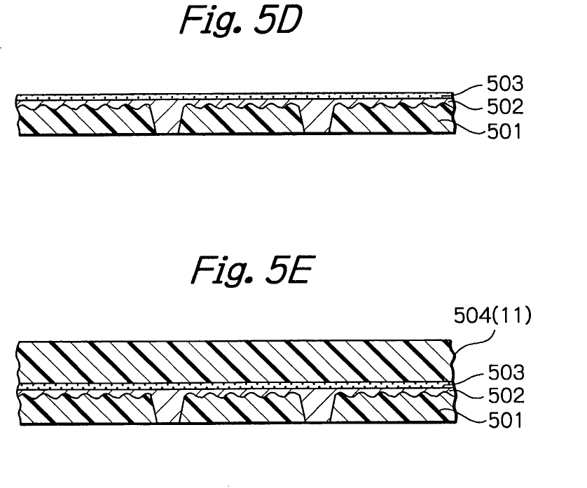

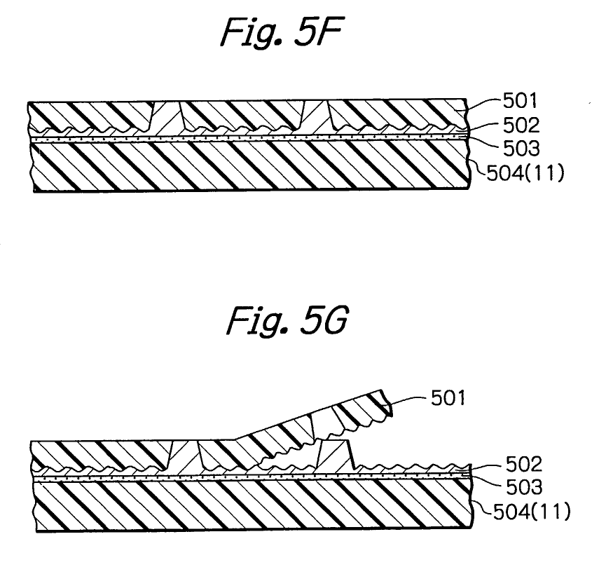

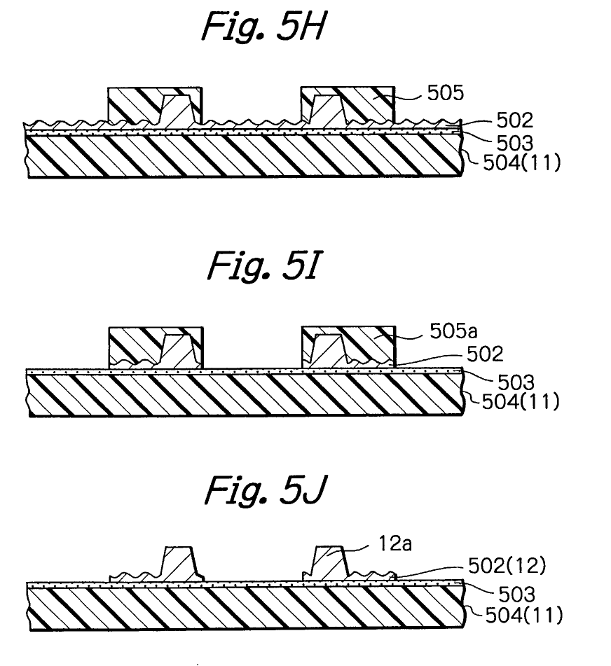

A first method for manufacturing the flip-chip type semiconductor device of FIG. 4 is explained next with reference to FIGS. 5A through 5J.

First, referring to FIG. 5A, tapered openings 501a corresponding to the bumps 13 of FIG. 4 are perforated in a resin substrate 501 made of polyimide resin or epoxy resin by a laser beam irradiation process, a photolithography and etching process, or a sandblasting process. As a result, the diameter of tapered openings 501a is smaller on the lower side than on the upper side.

Next, referring to FIG. 5B, in order to improve the contact characteristics between the resin substrate 501 and a plating conductive layer (see: 502 of FIG. 5C) which will be formed later, the surface 501b of the resin substrate 501 is roughened by a sandblasting process. For example, the degree of roughness of the surface 501b is about 1 to 10 μm, preferably, about 1 to 5 μm.

Next, referring to FIG. 5C, the resin substrate 501 is immersed into a plating catalyst solution (not shown), and then, is immersed into an electroless plating solution (not shown). As a result, a plating conductive layer 502 is formed on the surface 501b of the resin substrate 501 as well as within the tapered openings 501a thereof. In this case, after a part of the conductive layer 502 on the surface 501b of the resin substrate 501 is formed by an electroless plating process, a part of the conductive layer 502 within the tapered openings 501a of the resin substrate 501 can be formed by an electroplating process.

The bonding strength (peeling strength) between the conductive layer 502 and the resin substrate 501 is about 0.2 to 0.5 kg/cm due to the roughness of the surface 501b of the resin substrate 501.

Next, referring to FIG. 5D, an about 20 to 50 μm thick adhesive layer 503 is coated on the conductive layer 502. In this case, the material of the adhesive layer 503 is selected, so that the bonding strength (peeling strength) between the adhesive layer 503 and the conductive layer 502 is larger than that between the conductive layer 502 and the resin substrate 501. For example, the bonding strength (peeling strength) between the adhesive layer 503 and the conductive layer 502 is larger than about 1 kg/cm.

Next, referring to FIG. 5E, an about 100 to 300 μm thick resin substrate 504 corresponding to the resin substrate 11 of FIG. 4 is adhered to the adhesive layer 503. After the adhesive layer 503 is sufficiently hardened, the stacked configuration of FIG. 5E is reversed, so that the resin substrate 501 is located on the upper side as illustrated in FIG. 5F.

Next, referring to FIG. 5G, the resin substrate 501 is mechanically peeled off from the conductive layer 502. In this case, since the bonding strength (peeling strength) between the adhesive layer 503 and the conductive layer 502 is much larger than that between the conductive layer 502 and the resin substrate 501, the conductive layer 502 is never peeled off from the adhesive layer 503. Additionally, since the part of the conductive layer 502 within the resin substrate 501 is tapered, the resin substrate 501 is easily peeled off from the conductive layer 502.

Next, referring to FIG. 5H, a photoresist pattern layer 505 is formed by a photolithography process on the conductive layer 502.

Next, referring to FIG. 5I, the conductive layer 502 is etched by using the photoresist pattern layer 505 as a mask.

Next, referring to FIG. 5J, the photoresist pattern layer 505 is removed, so that the conductive layer 502 is converted into a conductive pattern layer 12 with bumps 12a as illustrated in FIG. 4.

Finally, a semiconductor pellet 2 of FIG. 4 is pressed thereto by a thermocompressing method or a heating and ultrasonic bonding method. Also, a resin layer 203 of FIG. 4 is inserted between the circuit board 1 and the semiconductor pellet 2 to complete the flip-chip type semiconductor device of FIG. 4. Note that the adhesive layer 503 is not shown in FIG. 4.

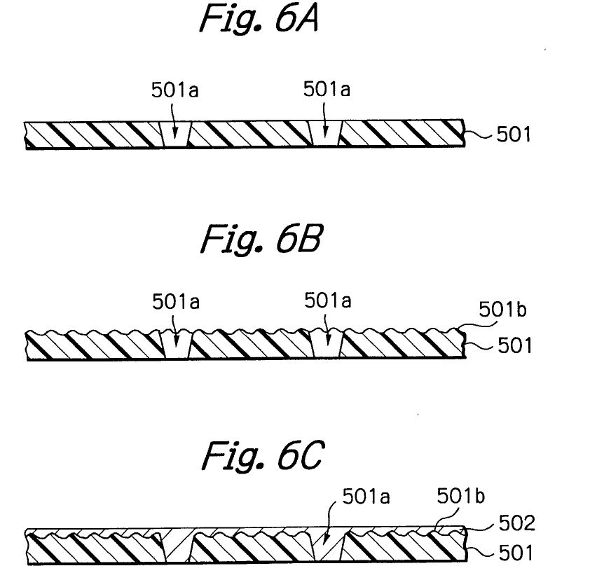

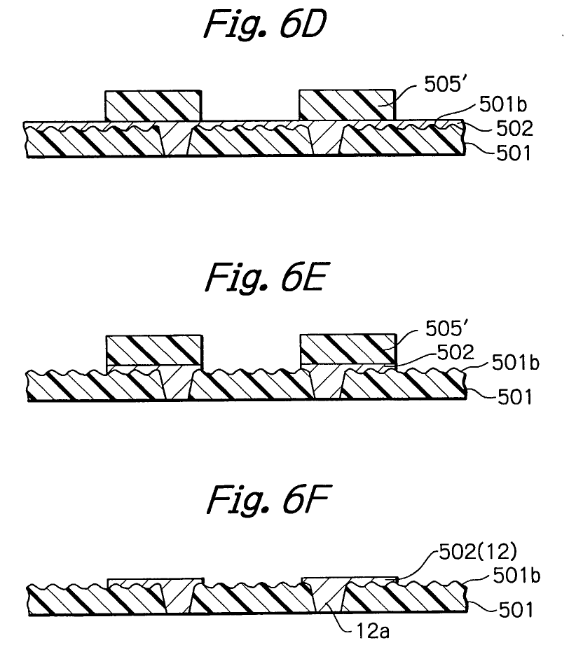

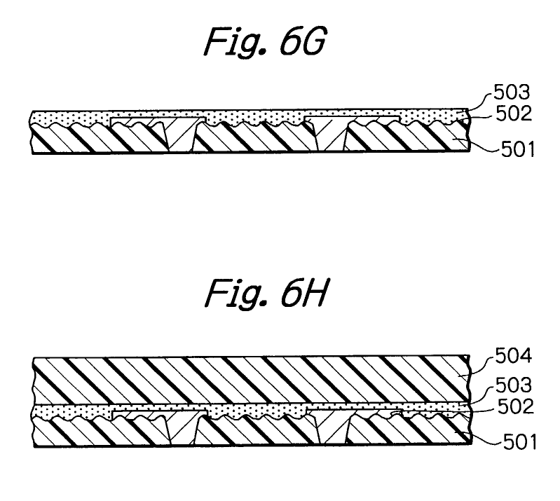

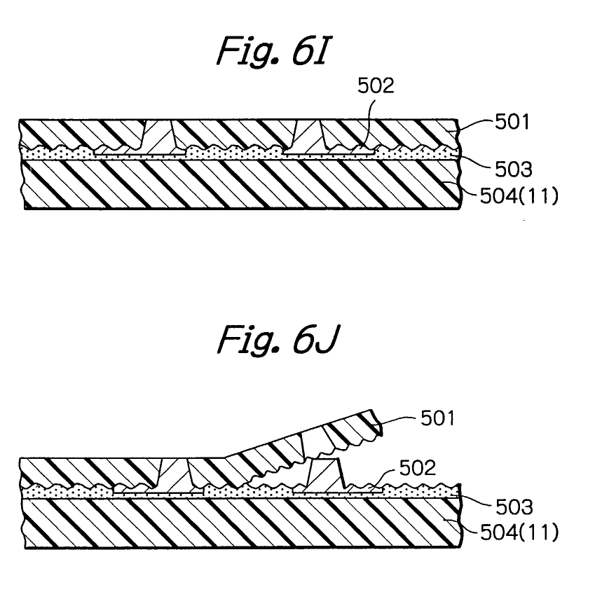

A second method for manufacturing the flip-chip type semiconductor device of FIG. 4 is explained next with reference to FIGS. 6A through 6J.

First, referring to FIG. 6A, in the same way as in FIG. 5A, tapered openings 501a corresponding to the bumps 13 of FIG. 4 are perforated in a resin substrate 501 made of polyimide resin or epoxy resin by a laser beam irradiation process, a photolithography and etching process, or a sandblasting process. As a result, the diameter of the tapered openings 501a is smaller on the lower side than on the upper side.

Next, referring to FIG. 6B, in the same way as in FIG. 5B, in order to improve the contact characteristics between the resin substrate 501 and a plating conductive layer (see: 502 of FIG. 6C) which will be later formed, the surface 501b of the resin substrate 501 is made coarse by a sandblasting process. For example, the degree of roughness of the surface 501b is about 1 to 10 μm, preferably, about 1 to 5 μm.

Next, referring to FIG. 6C, in the same way as in FIG. 5C, the resin substrate 501 is immersed into a plating catalyst solution (not shown), and then, is immersed into an electroless plating solution (not shown). As a result, a plating conductive layer 502 is formed on the surface 501b of the resin substrate 501 as well as within the tapered openings 501a thereof. In this case, after a part of the conductive layer 502 on the surface 501b of the resin substrate 501 is formed by a electroless plating process, a part of the conductive layer 502 within the tapered openings 501a of the resin substrate 501 can be formed by an electroplating process.

The bonding strength (peeling strength) between the conductive layer 502 and the resin substrate 501 is about 0.2 to 0.5 kg/cm due to the roughness of the surface 501b of the resin substrate 501.

Next, referring to FIG. 6D, a photoresist pattern layer 505′ is formed by a photolithography process on the conductive layer 502.

Next, referring to FIG. 6E, the conductive layer 502 is etched by using the photoresist pattern layer 505′ as a mask.

Next, referring to FIG. 6F, the photoresist pattern layer 505′ is removed, so that the conductive layer 502 is converted into a conductive pattern layer 12 with bumps 12a as illustrated in FIG. 4.

Next, referring to FIG. 6G, in the same way as in FIG. 5D, an about 20 to 50 μm thick adhesive layer 503 is coated on the conductive layer 502 and the resin substrate 501. In this case, the material of the adhesive layer 503 is selected, so that the bonding strength (peeling strength) between the adhesive layer 503 and the conductive layer 502 is larger than that between the conductive layer 502 and the resin substrate 501. For example, the bonding strength (peeling strength) between the adhesive layer 503 and the conductive layer 502 is larger than about 1 kg/cm.

Next, referring to FIG. 61I, in the same way as in FIG. 5E, an about 100 to 300 μm thick resin substrate 504 corresponding to the resin substrate 11 of FIG. 4 is adhered to the adhesive layer 503. After the adhesive layer 503 is sufficiently hardened, the stacked configuration of FIG. 6H is reversed, so that the resin substrate 501 is located on the upper side as illustrated in FIG. 6I.

Next, referring to FIG. 6J, in the same way as in FIG. 5G, the resin substrate 501 is mechanically peeled off from the conductive layer 502. In this case, since the bonding strength (peeling strength) between the adhesive layer 503 and the conductive layer 502 is much larger than that between the conductive layer 502 and the resin substrate 501, the conductive layer 502 is never peeled off from the adhesive layer 503. Additionally, since the part of the conductive layer 502 within the resin substrate 501 is tapered, the resin substrate 501 is easily peeled off from the conductive layer 502.

Finally, a semiconductor pellet 2 of FIG. 4 is pressed thereto by a thermocompressing method or a heating and ultrasonic bonding method. Also, a resin layer 203 of FIG. 4 is inserted between the circuit board 1 and the semiconductor pellet 2 to complete the flip-chip type semiconductor device of FIG. 4. Note that the adhesive layer 503 is not shown in FIG. 4.

In the above-described embodiment, although the adhesive layer 503 is coated on the conductive layer 503, the adhesive layer 503 can be coated on the resin substrate 504 in advance. Additionally, if the bonding pads 22 of the semiconductor chip 21 is made of thick Au, the bumps 22 can be surely in contact with the bonding 22 and the distance between the printed circuit board 1 and the semiconductor pellet 2 can be increased.

As explained hereinabove, according to the present invention, since a conductive pattern layer with bumps are mechanically transferred to an insulating substrate of a printed circuit board without using an etching process, the manufacturing cost can be remarkably decreased.

1. A printed circuit board comprising:
an insulating substrate; and
a plating conductive pattern layer including bumps formed on said insulating substrate.

2. The printed circuit board as set forth in claim 1, wherein said insulating substrate comprises a resin substrate.

3. A method for manufacturing a printed circuit board, comprising the steps of:
perforating openings in a first resin substrate;
forming a conductive layer on a surface of said first resin substrate and within said openings of said first resin substrate;
adhering a second resin substrate to said conductive layer by an adhesive layer; and
peeling off said first resin substrate from said conductive layer, so that said conductive layer is transferred from said first resin substrate to said second resin substrate.

4. The method as set forth in claim 3, wherein said openings are tapered, so that a cross section of said openings is larger on the side of said surface of said first resin substrate than on the side of another surface of said first resin substrate.

5. The method as set forth in claim 3, further comprising a step of roughening said surface of said first resin substrate so that a bonding strength between said conductive layer and said first resin substrate is increased, before said conductive layer is formed.

6. The method as set forth in claim 5, wherein a degree of roughness of said surface of said first resin substrate is about 1 to 10 μm.

7. The method as set forth in claim 5, wherein a bonding strength between said adhesive layer and said second resin substrate is larger than a bonding strength between said conductive layer and said first resin substrate.

8. The method as set forth in claim 3, further comprising a step of patterning said conductive layer to form a conductive pattern layer, after said first resin substrate is peeled off.

9. The method as set forth in claim 3, further comprising a step of patterning said conductive layer to form a conductive pattern layer, before said second resin substrate is adhered to said conductive layer.

10. The method as set forth in claim 3, wherein said conductive layer forming step forms said conductive layer by an electroless plating process.

11. The method as set forth in claim 3, wherein said conductive layer forming step comprises the steps of:
forming a part of said conductive layer on said surface of said first resin substrate by an electroless plating process; and
forming a part of said conductive layer within said openings by an electroplating process.

12. The method as set forth in claim 3, further comprising a step of coating said adhesive layer on said conductive layer before said second resin substrate is adhered to said conductive layer.

13. The method as set forth in claim 3, further comprising a step of coating said adhesive layer on said second resin substrate before said second resin substrate is adhered to said conductive layer.

14. A method for manufacturing a printed circuit board, comprising the steps of:
perforating openings in a first resin substrate;
roughening a surface of said first resin substrate;
forming a conductive layer on said surface of said first resin substrate and within said openings of said first resin substrate;
adhering a second resin substrate to said conductive layer by an adhesive layer;
peeling off said first resin substrate from said conductive layer, so that said conductive layer is transferred from said first resin substrate to said second resin substrate; and
patterning said conductive layer to form a conductive pattern layer with bumps.

15. The method as set forth in claim 14, wherein said openings are tapered, so that a cross section of said openings is larger on the side of said surface of said first resin substrate than on the side of another surface of said first resin substrate.

16. A method for manufacturing a printed circuit board, comprising the steps of:
perforating openings in a first resin substrate;
roughening a surface of said first resin substrate;
forming a conductive layer on said surface of said first resin substrate and within said openings of said first resin substrate;
patterning said conductive layer to form a conductive pattern layer with bumps;
adhering a second resin substrate to said conductive pattern layer by an adhesive layer; and
peeling off said first resin substrate from said conductive layer, so that said conductive pattern layer with said bumps is transferred from said first resin substrate to said second resin substrate.

17. The method as set forth in claim 16, wherein said openings are tapered, so that a cross section of said openings is larger on the side of said surface of said first resin substrate than on the side of another surface of said first resin substrate.
